(19) United States
(12) Patent Application Publication
(10) Pub. No.: US 2007/0090815 A1
(43) Pub. Date: Apr. 26, 2007

(54) Integrated circuit with power gating function

(75) Inventor: Shang-Chih Hsieh, NiaoSong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Faraday Technology Corp.

(21) Appl. No.: 11/257,592

(22) Filed: Oct. 24, 2005

(51) Int. Cl. H01L 29/768; G05F 1/00

(52) U.S. Cl. 323/269; 257/236

(57) ABSTRACT

An integrated circuit with power gating function is disclosed, comprising a low dropout regulator coupled to a first power line to provide power to the first power line, a switch module connected between a second power line and a voltage source, turned on and off based on a mode signal to determine whether the voltage source provides power to the second power line, and an equalizer connected between the first and second power lines, activated with the switch module based on the mode signal to equalize the voltage of the second power line to that of the first power line when the mode signal permits the voltage source to provide power to the second power line.

### BACKGROUND

The invention relates to integrated circuits and more particularly to integrated circuits with power gating function.

Increased prevalence of mobile application with attendant requirements for low power consumption and high speed have created demand for reduced size, operating voltage and threshold voltage of transistors. However, higher current leakage is induced in integrated circuit (IC) made up of low threshold voltage transistors when the IC is in static mode, increasing power consumption. Solutions have thus been attempted by developing an integrated circuit with power gating function. Generally, an IC can be divided into an I/O circuit comprising power-supply circuits and a core circuit comprising logic operation units and data storage units, both of the two units typically made up of small size transistors with low threshold voltage and low operating voltage. When an IC with power gating function is in active mode, power-supply circuits provide power to data storage units and logic operation units. However, when the IC is in static mode, power-supply circuits provide power to only data storage circuits and shut down logic circuits for reduced power consumption. Only some indispensable parts in logic units may be provided with power while other parts are shut down, such that a more economical use of power is achieved.

FIG. 1 shows a schematic diagram of a conventional integrated circuit with power gating function, comprising a first power line 100 coupled to a part of a data storage unit 106 (for example, D flip flops as shown) made up of low threshold voltage transistors, a second power line 102 coupled to a part of a logic operation unit 104 and another part of the logic data storage unit 106, wherein the logic operation unit 104 is also made up of low threshold voltage transistors, an interface unit 108 coupled between the logic operation unit 104 and the data storage unit 106, and a switch transistor 110 connecting the first power line 100 to the second power line 102. The switch transistor 110 as shown is typically a high threshold PMOS transistor with a gate coupled to a mode signal 102.

In FIG. 1, one part of the data storage unit 106 is illustrated shown is connected to the first power line 100 and another part is connected to the second power line 102. It should be clear to those skilled in the art that such connections depend on the design. For example, circuits in the data storage unit 106 can all connect with the first power line 100.

When the integrated circuit of power gating function is in active mode, the power line 100 supplies power to the part connected thereto. The mode signal 112 is at low level, turning on the switch transistor 110 and further permitting power to be supplied to the second power line 102 from the first power line 100. In response, both the logic operation unit 104 and the part connected to the second power line 102 in the data storage unit 102 are activated to operate normally. Concurrently, the data storage unit 104 passes data through the interface unit 108 to the data storage unit 106 for storage.

Alternatively, when the integrated circuit is in static mode, the mode signal 112 is at high level, turning off the switch transistor 110, preventing power supply to the second power line 102 from the first power line 100. Resultingly, the logic operation unit 104 and the part connected to the second power line 102 in the data storage unit 102 are shut down. However, the first power line 100 continues supplying power to the part connected thereto in data storage unit 106. This part thus can store the data received previously in active mode from the logic operation unit 104.

Although core circuits are generally devised to operate at low voltage, they are often connected to high voltage circuits to suit various applications. In such a configuration, a power-supply circuit includes a low dropout regulator to convert high level voltage provided by peripheral high voltage circuits to a low level voltage required to operate the core circuit.

FIG. 2 is a schematic diagram of a conventional integrated circuit with power gating function incorporating a low dropout regulator 200 coupled to and providing stable power to the first power line 100. FIG. 2 is in all respects the same as FIG. 1 excepting an addition of low dropout regulator 200, with a typical circuit structure shown there for. As shown, the low dropout regulator 200 comprises an operational amplifier 202, a reference voltage generator 204 providing a reference voltage irrelevant to parameters such as temperature and processing, a resistance voltage dividing circuit consisting of two series-wound resistors R1 and R2, and a first transistor 206 of P type coupled to a voltage source Vcc (for example, 3.3V). The source voltage of the first transistor 206 serves as an output voltage of the low dropout regulator 200. The output voltage is divided through the resistors R1 and R2, sequentially fedback to the operational amplifier 202, to for comparison therein with the reference voltage produced by the reference voltage generator 204. The output voltage of the operational amplifier 202 adjusts the gate voltage and effective resistance for the first transistor 206 based on the comparison result and thus stabilizes the output voltage.

However, several problems exist in the conventional integrated circuit of FIG. 2. First, performance of core circuit is poor and accuracy of timing model of core logic cells is low, due to the second power line 102, unlike the first power line 100 coupled to the low dropout regulator 200 and thus having stable voltage, coupling to the first power line 100 through the switch transistor 110. The second power line 102 is thus incapable of feeding back voltage to the low dropout voltage directly. In active mode, a voltage difference between the voltage of the second power line 102 and that of the first power line 100 is induced accordingly. Further, voltage of the second power line cannot be automatically stabilized by the low dropout regulator 200. As a result, the performance of the core circuit is degraded and accuracy of the timing model is low.

Secondly, considerable IC area is wasted by the switch transistor 110. To decrease the difference in the voltages of the second power line 102 and the first power line 100, the switch transistor 110, withstanding large current flowing to the second power line 200, requires large size, generally, about 10% of the IC core area. This large area increases current leakage. Size for the transistor 110 is thus an issue to comprise voltage deviation and current leakage.

Further, it is necessary to have a high threshold switch transistor 110 to reduce current leakage. However, such a high threshold switch transistor 110 cannot be produced with the same process as other low threshold transistors in the IC. Process fusion techniques are required, further increasing required masks and cost.

Finally, power efficiency in active mode is poor, due to electrical power conducted through the first transistor 206 and the switch transistor 110 before reaching the second power line 102. The power transistor 110 thus decreases power efficiency.

### SUMMARY

The invention provides integrated circuits with power gating function. The integrated circuits of the invention have smaller area, improved power consumption in both active mode and static mode, and can be produced in a signal process without process fusion.

An integrated circuit with power gating function in accordance with an embodiment of the invention comprises a first low dropout regulator coupled to a first power line and a second low dropout regulator coupled to a second power line and activated by a mode signal. When the integrated circuit is in active mode, the mode signal turns on the second low dropout regulator such that the second low dropout regulator can supply power to the second power line, and when the integrated circuit is in static mode, the mode signal shuts down the second low dropout regulator, interrupting power to the second power line.

The invention also provides an integrated circuit comprising a low dropout regulator coupled to a first power line, a switch module connecting a second power line and a voltage source, and an equalizer connecting the first and second power lines, wherein the switch module and the equalizer are controlled by a mode signal to turn on and off. When the integrated circuit is in active mode, the mode signal turns on the switch module and the equalizer, such that the voltage source provides power to the second power line and concurrently the equalizer equalizes the voltage of the second power line with that of the first power line. When the integrated circuit is in static mode, the mode turns off the switch module, preventing the voltage source from providing power to the second power line, and shuts down the equalizer.

### BRIEF DESCRIPTION OF THE DRAWINGS

The foregoing and other advantages and features of the invention will become more apparent from the detailed description of embodiments of the invention given below with reference to the accompanying drawings in which:

FIG. 1 is a circuit diagram of a conventional integrated circuit with power gating function;

FIG. 2 is a circuit diagram of a conventional integrated circuit with power gating function incorporated with a low dropout regulator;

FIG. 3 is a circuit diagram of an integrated circuit with power gating function in accordance with an embodiment of the invention;

FIG. 4 is a circuit diagram of an integrated circuit with power gating function in accordance with another embodiment of the invention.

### DETAILED DESCRIPTION

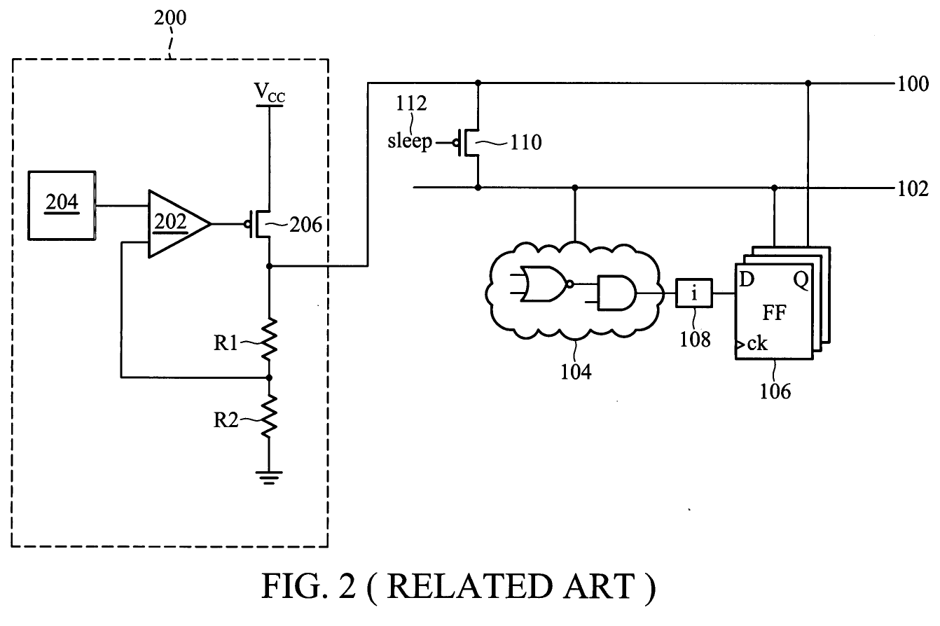

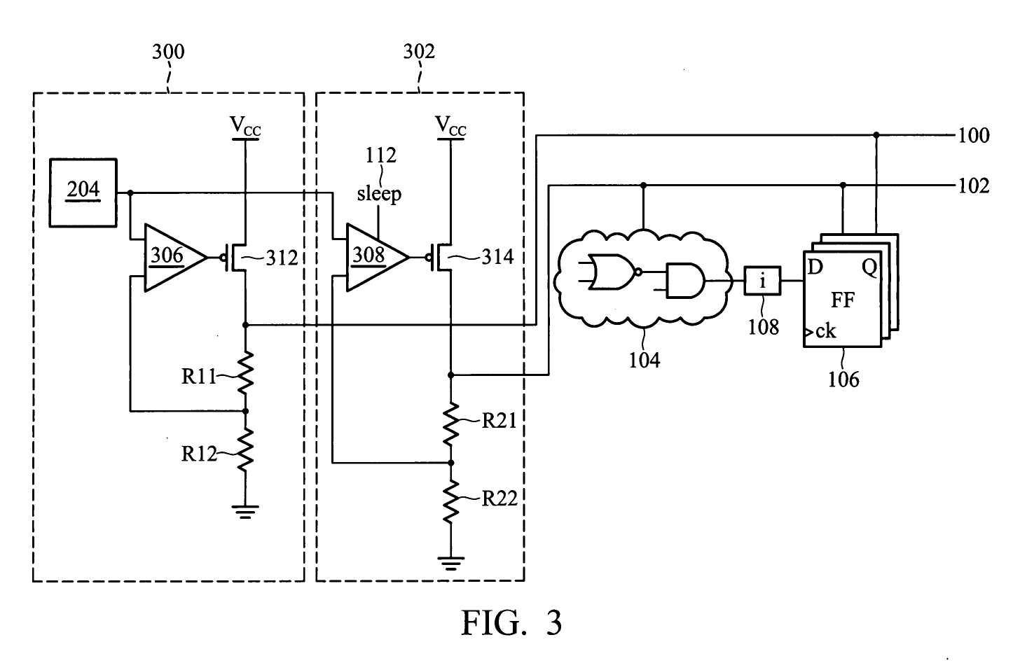

FIG. 3 is a schematic diagram of an integrated circuit with power gating function in accordance with an embodiment of the invention. The integrated circuit comprises a first low dropout regulator 300 coupled to a first power line to provide power to a part connected to the first power line 100 in a data storage unit 106, and a second low dropout regulator 302 coupled to a second power line to provide power to a logic operation unit 104 and another part connected to the second power line 106 in the data storage unit 106. Like the low dropout regulator in FIG. 2, the first low dropout regulator 300 typically comprises a reference generator 204, an operational amplifier 306, a PMOS-transistor 312 coupled to a voltage source Vcc, and two resistors R11 and R12. Similarly, the second low dropout regulator 302 comprises an operational amplifier 308 and a PMOS transistor 314 coupled to the voltage source Vcc, and uses the reference voltage generator 204 together with the first low dropout regulator 300. The operational amplifier 308 in the second low dropout regulator 302 is controlled by a mode signal 112 to turn on or off, determining whether the second low dropout regulator 302 provides power to the second power line 102.

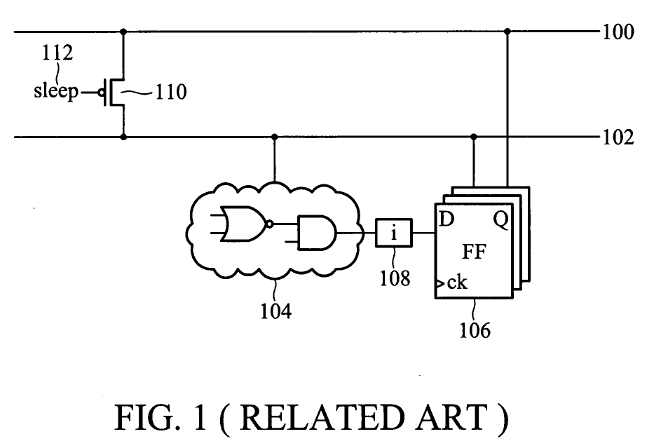

As with FIG. 1, the data storage unit 106 requires no connection both to the first power line 100 and the second power line 102, as shown in FIG. 3. For example, all the circuits in the data storage unit 106 can be connected to the first power line 100.

When the integrated circuit is in active mode, the first low dropout regulator 300 provides stable power to the first power line 100, activating the part connected to the first power line 100 in the data storage unit 106. Concurrently, the mode signal is at low level, so the operational amplifier 308 operates normally and turns on the PMOS transistor 314. As a result, the voltage Source Vcc provides stable voltage to the logic operation unit 104 and the part connected to the second power line 102 in the data storage unit 106 through the second power line 102.

Alternatively, when the integrated circuit is in static mode, the first low dropout regulator 300 continues providing power to the first power line, and the part connected to the fist power line 100 in the data storage unit 106 operates normally. Concurrently, the mode signal 112 is at high level, driving the operational amplifier 308 to output a high level voltage and turn off the PMOS transistor 314. The voltage source VCC is thus prevented from providing power supply to the second power line 102. As a result, the logic operation unit 104 and the part connected to the second power line 102 in the data storage unit 106 are both shut down.

As shown in FIG. 3, power to the second power line 102 in active mode is provided directly by the second low dropout regulator 302 without passing through the switch transistor 110, with no voltage difference between the first and second power lines as described in connection with FIG. 2. Further, since the second low dropout regulator compensates and stabilizes the voltage of the second power line 102, voltages provided through the second power line 102 to the logic operation unit 104 and the data storage unit 106 are stable. As a result, low timing accuracy and degraded unit performance occurring in the conventional integrated circuit of FIG.2 are solved.

The integrated circuit with power gating function in accordance with the embodiment of the invention provides further advantages. First, because static mode is driven by turning off the transistor 304 directly connected to the voltage source Vcc, current leakage and power consumption are reduced. Secondly, area occupied by the switch transistor 110 is conserved, as is core area of IC. Although the IC of the embodiment has one more low dropout regulator than that of FIG. 2, the total area of the first and second low dropout regulators is almost the same as that of the signal low dropout regulator in FIG.2, since the first and second regulators provide current to the first and second power lines respectively. Because the total current is not changed, with current corresponding to area, the area occupied by the first and second regulators does not change. Thus, without the area occupied by the switch transistor 110, the total IC area of the invention is less than that of FIG. 2. Further, the process fusion technique due to the high threshold voltage switch transistor 110 in producing core circuit is no longer required. Further, current flows only through the transistor 314 without passing through the switch transistor 110, improving power efficiency.

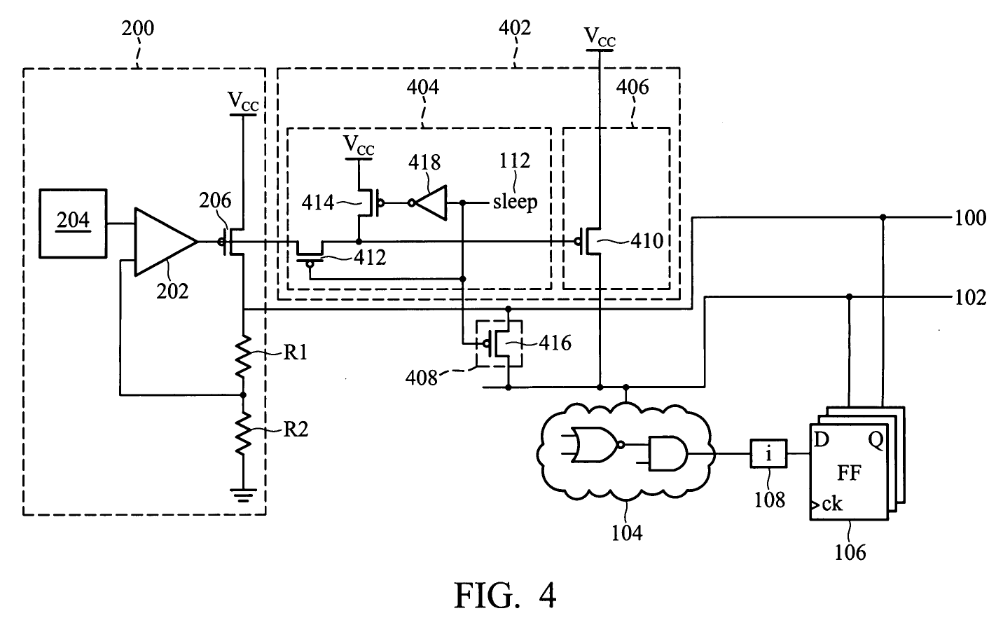

FIG. 4 shows a schematic diagram of an integrated circuit in accordance with another embodiment of the invention. The integrated circuit comprises a low dropout regulator 200 to provide power to a part connected to a first power line 100 in a data storage unit 106 through the first power line 100, a switch module 402 consisting of a control module 404 and a switch 406. The switch 406 is connected between a voltage source Vcc and a second power line 102. The control module 404 has an input terminal of the control module 404 coupled to a mode signal 112 and an output terminal coupled to the switch 406. The mode signal controls the switch 406 via the control module 404 to determine whether the voltage source Vcc provides power to a logic operation unit 104 and another part connected to the second power line 106 in the data storage unit 106. The integrated circuit with power gating function further comprises an equalizer 108 connected between the first power line 100 and the second power line 200. The equalizer 108 is activated by the mode signal 112 simultaneously with the switch module 402, equalizing the voltage of the second power line 102 with that of the-first power line when the voltage source provides power to the second power line 102.

As with FIGS. 1 and 3, the data storage unit 106 requires no connection as in FIG. 3 with the first power line 100 and the second power line 102. For example, all the circuits in the data storage unit 106 can be connected to the first power line 100.

When the integrated circuit is in active mode, the low dropout regulator 200 provides power to both a logic operation unit 104 and another part connected to the second power line 102 in the data storage unit 106 through the first power line 100. Also, the mode signal 112 turns on the switch 406 via the control module, permitting the voltage source to provide power to the second power line 102. The logic operation unit 104 and the part connected to the second power line 106 in the data storage unit 106 are thus activated. Concurrently, the equalizer 408 is also turned on to make the voltage of the second power line 102 substantially equal to that of the first power line 100.

Alternatively, when the integrated circuit is in static mode, the low dropout regulator 200 continues providing power to the first power line 100 and the part connected to the first power line 100 in the data storage unit 106 operates normally. However, the mode signal 112 turns off the switch 406 via the control module 404, preventing the voltage source Vcc from providing power to the second power line 102, and shuts down the equalizer 408. Resultingly, the logic operation unit 104 and the part connected to the second power line 100 in the data storage unit 102 are shut down.

As shown in FIG. 4, when the integrated circuit is in active mode, stabilization of the voltage of the first power line 100 is performed directly because the first power line is connected directly to the low dropout regulator 200. The second power line 200, however, requires the equalizer 408 to communicate the low dropout regulator 200, and thus utilizes indirect stabilization.

As shown in FIG. 4, the switch 406 in the switch module 402 is a switch transistor 410 of p type. The control module 404 comprises a third transistor 412 a fourth transistor 414, both of which are P type. The third transistor 412 has a gate coupled to the mode signal 112, a source coupled to the gate of the first transistor 206, and a drain coupled to the gate of the switch transistor 410 and the drain of the fourth transistor 414. The third transistor 412 passes the gate voltage of the first transistor 206 to the gate of the switch transistor 410. The mode signal 112 is coupled to the gate of the fourth transistor 414 via an inverter 418, wherein the source of the fourth transistor 414 is coupled to the voltage source Vcc, such that the high voltage level of the voltage source Vcc is transmitted through the fourth transistor 414 to turn off the switch transistor 410 when the integrated circuit is in static mode. The equalizer 418 is implemented with an equalization transistor 416 of P type having low threshold voltage. The equalization transistor 416 has a source coupled to the first power line 100, a drain coupled to the second power line 102, and a gate coupled to the mode signal 112. It should be obvious to those skilled in the art that all transistors can be opposite types to provide the same function.

When the integrated circuit is in active mode, the mode signal 112 is at a low level and is further inverted to a high level by the inverter 418. Responsively, the third transistor 412 is turned on when the fourth transistor 414 is turned off. The gate voltage of the first transistor 206 thus turns on the switch transistor 410, permitting the voltage source Vcc to supply power to the second power line 102. Concurrently, the equalization transistor 416, due to the low gate voltage is turned on, permitting the voltage of the second power line 102 to be substantially equal to that of the first power line 100. Voltage stabilization for the second power line 102 is thereby achieved.

Alternatively, when the integrated circuit is in static mode, the mode signal 112 is at a high level and is further inverted to low level by the inverter 418. Responsively, the third transistor 412 is turned off while the fourth transistor 414 is turned on. The gate voltage of the first transistor 206 thus turns off the switch transistor 410, preventing the voltage source Vcc from providing power to the second power line 102. Concurrently, the equalization transistor 416, due to the high gate voltage is turned off.

When the IC is in active mode, current from the voltage source Vcc to the second power line 102 through the switch transistor 410 exceeds that through the equalization transistor 416, such that the equalization transistor 416 needs not to be large size. Moreover, the static mode is driven by turning off the switch transistor 410 rather than the equalizer 416, so the equalization transistor 416 needs not to be a high threshold voltage transistor, since the equalization transistor 416 is used only to communicate the two power lines such that the voltage of the second power line 102 is adjusted indirectly by the low dropout regulator 200 and hence substantially equal to the first power line 100.

Since the power to the second power line 102 in active mode is provided directly by the second low dropout regulator 302 without passing through the switch transistor 110, no voltage difference occurs between the first and second power lines as described FIG. 2. Moreover, since the second power line 102 is coupled to the first power line 100 via the equalization transistor 416, and the gate of the switch transistor 410 is coupled to that of the first transistor 206, the second low dropout regulator compensates and stabilizes the voltage of the second power line 102. As a result, voltage provided to the logic operation unit 104 and the data storage unit 106 by the second power line 102 is stable. Low timing accuracy and poor performance in the conventional integrated circuit of FIG. 2 are thus solved.

The integrated circuit with power gating function in accordance with the embodiment of the invention provides further advantages. First, because the static mode is driven by turning off the switch transistor 410 directly connected to the voltage source Vcc, current leakage and power consumption are reduced. Secondly, area occupied by the switch transistor 110 is conserved, as is core area of IC. Although the IC of the embodiment has one more switch transistor 410 and control module 404, and replaces the switch transistor 110 with the equalization transistor 416, the total area of the first and second low dropout regulators is almost the same as that of the signal low dropout regulator in FIG. 2, since the first transistor 206 and the switch transistor 416 withstand current to the first and second power lines respectively. Because the total current is not changed, with current corresponding to area, the area occupied by the first and second regulators does not change. Moreover, the control module 404 is only for logic purpose and hence occupies small size. Further, the equalization transistor 416 withstands a small current induced by a small voltage difference between the first and second power lines and thus is small. The IC area of the invention is less than that shown in FIG. 2. Further, since the equalizer 410 is not required to have a high threshold voltage, the process fusion technique producing a conventional integrated circuit due to the high threshold switch transistor 110 is no longer required. Further, current flows only through the switch transistor 410 without passing through the switch transistor 110, improving the power efficiency.

It is noted that the integrated circuit of the invention in FIG. 4 has one operational amplifier and two resistors. Compared with the integrated circuit shown in FIG. 3 having two operational amplifier and four resistors, the integrated circuit shown in FIG. 4 is smaller. It will be obvious to those of ordinary skill in the art that the circuit configurations for the switch module, control module and equalizer can be modified to provide the same function.

While the invention has been described by way of example and in terms of the preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What claimed is:

1. An integrated circuit, comprising:
a first low dropout regulator coupled to and providing power to a first power line; and
a second low dropout regulator coupled to and providing power to a second power line based on a mode signal.

2. The integrated circuit as claimed in claim 1, further comprising a data storage unit connected between the first power line and a ground line, and a logic operation unit connected between the second power line and the ground line.

3. The integrated circuit as claimed in claim 1, further comprising a data storage unit having a first part connected between the first power line and a ground line and a second part connected between the second power line and the ground line, and a logic operation unit connected between the second power line and the ground line.

4. The integrated circuit as claimed in claim 1, wherein when the integrated circuit is in active mode, the mode signal directs the second low dropout regulator to provide power.

5. The integrated circuit as claimed in claim 1, wherein when the integrated circuit is in active mode, the mode signal commands the second low dropout regulator to interrupt power.

6. An integrated circuit, comprising:
a low dropout regulator coupled to a first power line to provide power to the first power line;
a switch module connected between a first power line and a voltage source, turned on and off based on a mode signal to determine whether the voltage source provides electric power to the second power line; and
an equalizer connected between the first and second power lines, activated with the switch module based on a mode signal, to equalize the voltage of the second power line with that of the first power line when the voltage source provides power to the second power line.

7. The integrated circuit as claimed in claim 6, further comprising a data storage unit connected between the first power line and a ground line, and a logic operation unit connected between the second power line and the ground line.

8. The integrated circuit as claimed in claim 6, further comprising a data storage unit having a first part connected between the first power line and a ground line and a second part connected between the second power line and the ground line, and a logic operation unit connected between the second power line and the ground line.

9. The integrated circuit as claimed in claim 6, wherein when the integrated circuit is in active mode, the mode signal turns on the switch module.

10. The integrated circuit as claimed in claim 9, wherein when the integrated circuit is in static mode, the mode signal turns off the switch module.

11. The integrated circuit as claimed in claim 10, wherein the switch module comprises a switch and a control module having an output terminal outputting different voltages based on the mode signal to control the switch.

12. The integrated circuit as claimed in claim 11, wherein the switch is a switch transistor having a gate coupled to the terminal of the control module, a first source/drain coupled to the voltage source, and a second source/drain coupled to the second power line.

13. The integrated circuit as claimed in claim 12, wherein the low dropout regulator comprises an operational amplifier, a reference voltage generator, a resistance voltage divider, and a first transistor, wherein one input of the operational amplifier is coupled to the reference voltage generator, the other input terminal of the operational amplifier is coupled to the input terminal of the resistance voltage divider, and the first transistor has a gate connected to the output terminal of the operational amplifier, a first source/drain coupled to the voltage source and a second source/drain coupled to the input terminal of the resistance voltage divider and the first power line.

14. The integrated circuit as claimed in claim 13, wherein when the integrated circuit is in active mode, the output terminal of the control module passes the gate voltage of the first transistor to the switch transistor to control the degree of turning on for the switch transistor.

15. The integrated circuit as claimed in claim 6, wherein the equalizer is a transistor having a gate controlled by the mode signal and first and second source/drains connected to the second power line.

16. The integrated circuit as claimed in claim 7, wherein the equalizer, the data storage unit, and the logic operation unit are produced in a common process.
